(19) United States
(12) Patent Application Publication
(10) Pub. No.: US 2026/0173305 A1
(43) Pub. Date: Jun. 18, 2026

(54) SERVER

(71) Applicant: Fulian Precision Electronics (Tianjin) Co., LTD., Tianjin (CN)

(72) Inventors: XIAO-LI YAN, Tianjin (CN); LIANG GAO, Tianjin (CN); YA-NI ZHANG, Tianjin (CN); FANG-XING YANG, Tianjin (CN); WEN-TZU CHEN, New Taipei (TW); QING-SONG ZENG, New Taipei (TW); CHEN-HAO SU, New Taipei (TW); XIANG-YU LEI, New Taipei (TW); LI-PING CHEN, New Taipei (TW); HONG-ZHANG LIN, New Taipei (TW)

(21) Appl. No.: 19/212,976

(22) Filed: May 20, 2025

(30) Foreign Application Priority Data
Dec. 17, 2024 (CN) 202411856787.1

(51) Int. Cl. H05K 7/20; H05K 7/14

(52) U.S. Cl. CPC H05K 7/20172; H05K 7/1402; H05K 7/1489; H05K 7/20727

(57) ABSTRACT

A server includes a case with an opening, a bracket movable between a working position and a maintaining position within the case, a chassis slidable into or out of the case through the opening, and a fan positioned in the chassis. The bracket is configured to hold electronic devices. When the chassis is inside the case and the bracket is in the working position, the bracket is located between the fan and the opening, enabling the fan to cool the electronic devices efficiently. When the bracket is moved to the maintaining position, it clears the path between the fan and the opening, allowing the chassis to slide out of the case for easy fan removal or maintenance and slide back in, improving operational convenience.

### FIELD

The disclosure herein generally relates to information computing systems, and more particularly relates to a server.

### BACKGROUND

Servers are usually equipped with a fan, and the fan sometimes needs to be removed from the server for maintenance or replacement. However, due to the compact structure of the server, removing the fan requires disassembling the server's case to take out the fan, which is complex and time-consuming.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a portion of a server in an embodiment of the present application.

FIG. 2 is another isometric view of the portion of the server shown in FIG. 1.

FIG. 3 is an isometric view of the portion of the server shown in FIG. 1, showing a bracket in a working position.

FIG. 4 is an isometric view of the portion of the server show in FIG. 3, showing the bracket in a maintaining position.

FIG. 5 is an isometric view of the portion of the server shown in FIG. 4, showing the bracket in the maintaining position and a fan pulled out from a cavity.

FIG. 6 is an isometric view from a front side of a chassis and the fan shown in FIG. 3, showing the fan installed in the chassis.

FIG. 7 is an isometric view from a rear side of the chassis and the fan shown in FIG. 6.

FIG. 8 is an exploded view of the chassis shown in FIG. 6.

FIG. 9 is an enlarged view of the area labeled IX in FIG. 6.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

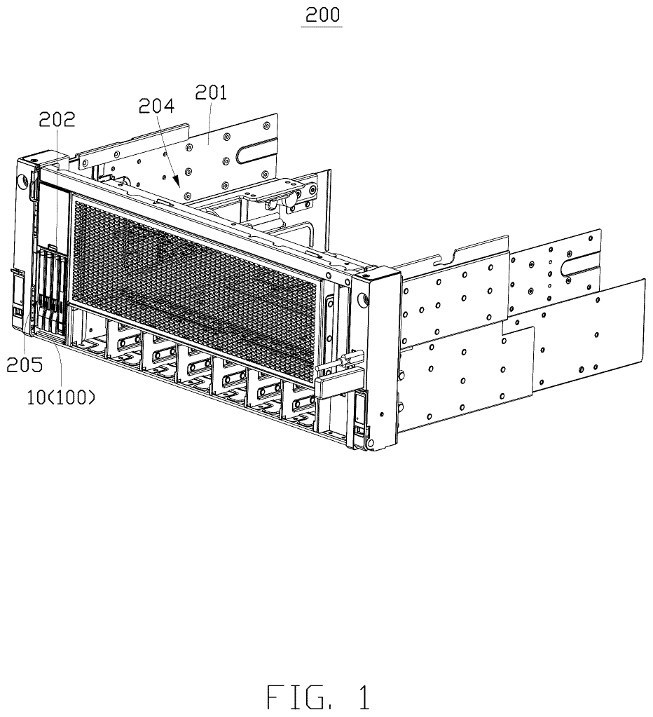

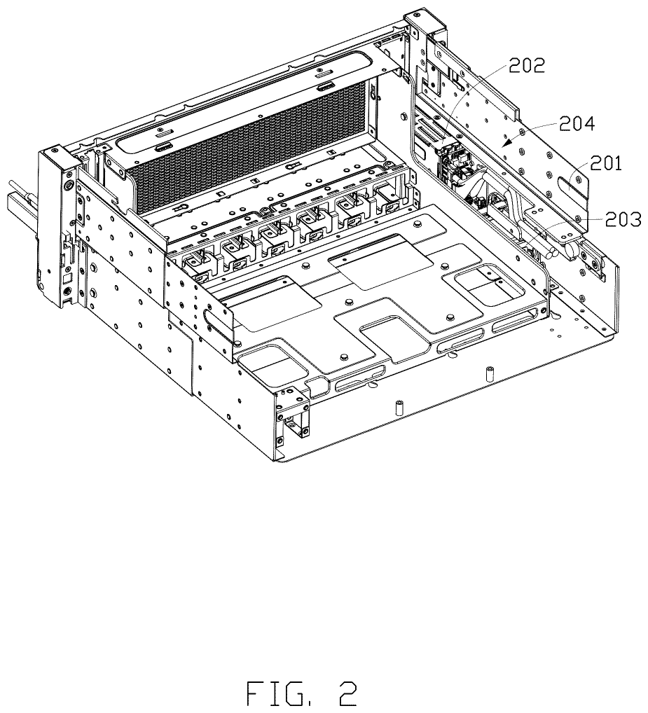

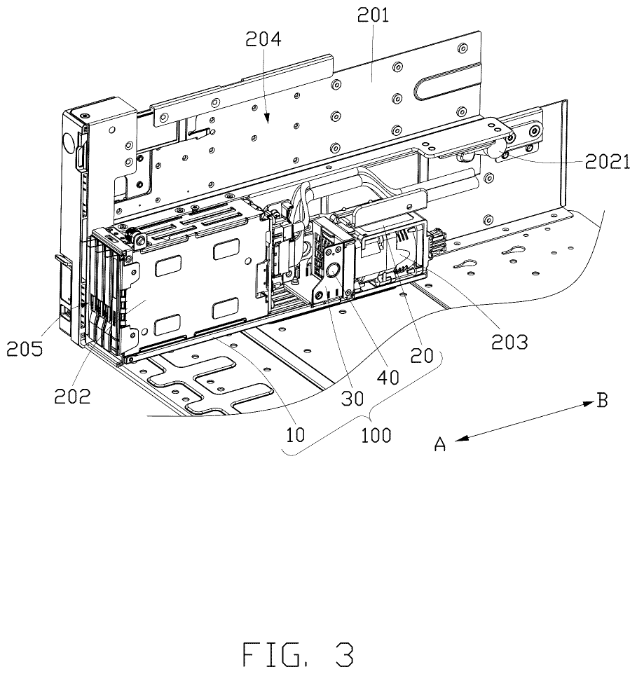

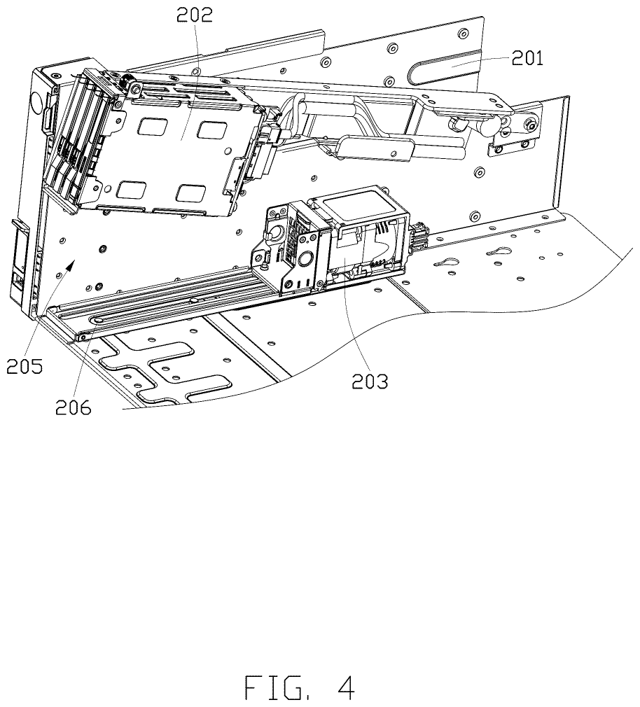

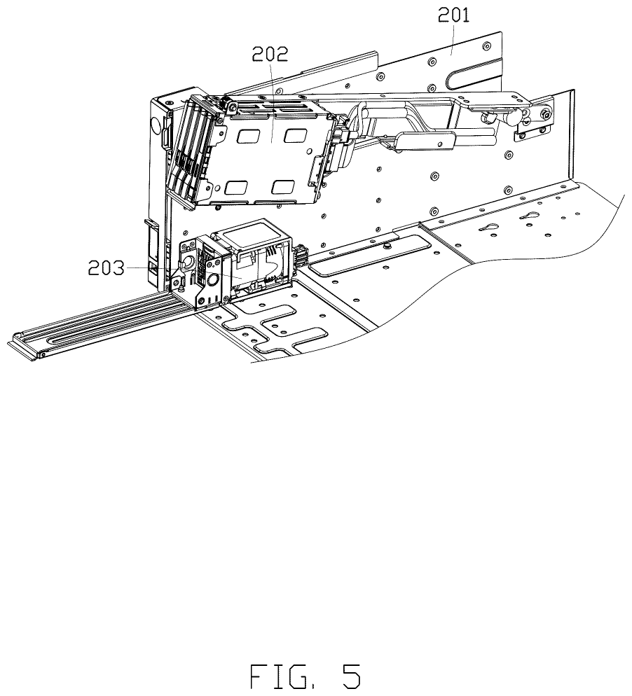

As shown in FIG. 1 to FIG. 5, an embodiment of the present application provides a server 200 including a case 201, bracket 202, a chassis 100, and a fan 203. The case 201 has a cavity 204 and an opening 205, the opening 205 is at the front side of the case 201. The bracket 202 is disposed within the cavity 204, the bracket 202 is used for mounting hard disks or PCIe cards (peripheral component interconnect express card). The inner end of the bracket 202 is rotatably connected to the case 201, and the bracket 202 can rotate relative to the case 201 between a working position (FIG. 3) and a maintaining position (FIG. 4 and FIG. 5). The case 201 is provided with a pin 206 (FIG. 4) on the bottom surface within the cavity 204, the pin 206 is, for example, a T-shaped pin.

The bracket 202 is rotatable around a shaft 2021 located on the case 201, as shown in FIG. 3, the shaft 2021 is perpendicular to a direction of slide of the chassis 100 relative to the case 201, when the chassis 100 is in the case 201 and when the bracket 202 is in the working position, the bracket 202 is between the fan 203 and the opening 205, and the shaft 2021 is on a side of the fan 203 away from the opening 205.

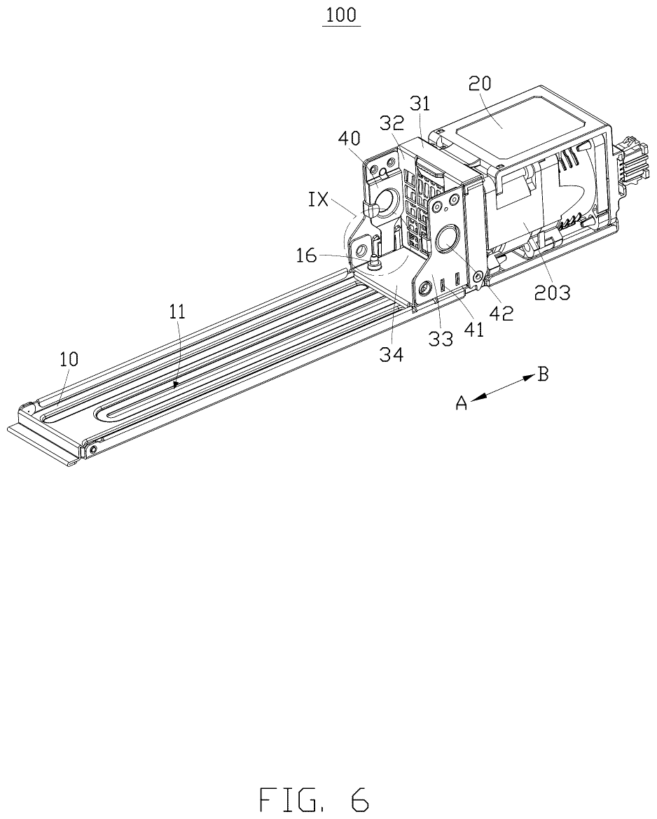

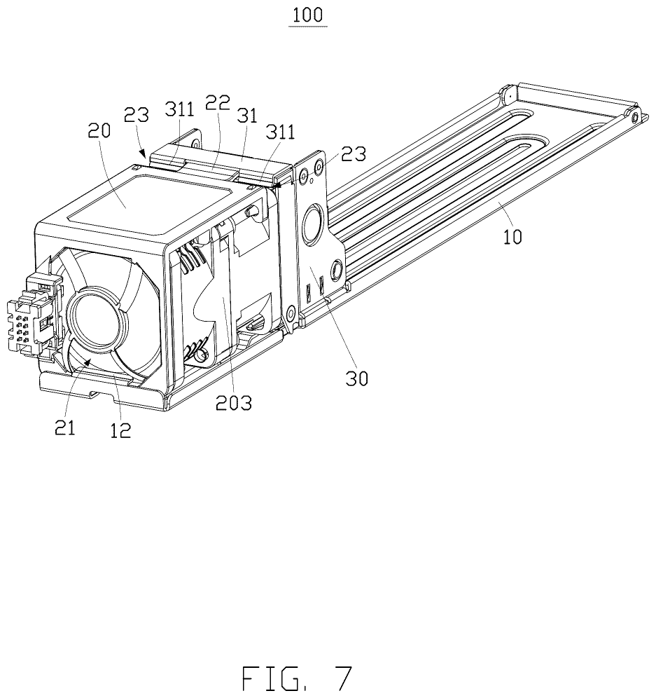

As shown in FIG. 6 to FIG. 8, the chassis 100 includes a sliding board 10, a frame 20, a lock 30, and two elastic pieces 40. The sliding board 10 is provided with a sliding groove 11, the sliding groove 11 extends along the length of the sliding board 10. The pin 206 passes through the sliding groove 11, allowing the sliding board 10 to slide relative to the case 201 in an A direction or a B direction, the A direction and the B direction are opposite to each other. The tail end of the sliding board 10 has a plug-board 12. The fan 203 is installed within the frame 20. The frame 20 is disposed at the tail end of the sliding board 10, and the bottom of the rear side of the frame 20 has a plug-slot 21. The plug-board 12 is inserted into the plug-slot 21 along the A direction, the plug-board 12 is used to fix the rear side of the frame 20 to the sliding board 10, preventing the rear side of the frame 20 from lifting. The lock 30 is disposed on the sliding board 10 and located at the front side of the frame 20. The lock 30 has a pressing board 31, the pressing board 31 is used to press down on the top of the front side of the frame 20 to secure the frame 20 to the sliding board 10, preventing the front side of the frame 20 from lifting. The two elastic pieces 40 are respectively disposed on opposite sides of the lock 30. Each elastic piece 40 is provided with a buckle 41, and the sliding board 10 is provided with a positioning slot 13 at a position corresponding to the buckle 41. The buckle 41 is used to insert into the positioning slot 13 to lock the lock 30 onto the sliding board 10.

When a user needs to remove the fan 203, as shown in the sequence from FIG. 3 to FIG. 5, the user first rotates the bracket 202 upward to the maintaining position. When the bracket 202 is in the maintaining position, the bracket 202 is located above the fan 203(the bracket 202 is not between the opening 205 and the fan 203). Then, the user pulls the sliding board 10 out of the cavity 204. Next, the user can remove the lock 30 from the sliding board 10. At this time, the user manually presses the elastic piece 40, and after the elastic piece 40 deforms under pressure, the buckle 41 is pulled out of the positioning slot 13, allowing the user to remove the lock 30 from the sliding board 10. After removing the lock 30, the user can easily detach the frame 20 from the sliding board 10. Since the fan 203 is within the frame 20, the user can open the detached frame 20 to perform maintenance or replacement of the fan 203.

Conversely, when reinstalling the fan 203 into the case 201, as shown in the sequence from FIG. 5 to FIG. 3, the user first places the frame 20 with the installed fan 203 onto the sliding board 10, ensuring that the plug-board 12 is inserted into the plug-slot 21. Then, the user installs the lock 30 onto the sliding board 10, at which point the buckle 41 inserts into the positioning slot 13, and the pressing board 31 presses down on the frame 20, securing the frame 20 to the sliding board 10. Next, the user pushes the sliding board 10 back into the cavity 204. Finally, after the sliding board 10 is fully slid into the cavity 204, the user rotates the bracket 202 downward to the working position. When the bracket 202 is in the working position, the fan 203 is located behind the bracket 202 and blows air toward the front bracket 202, thereby cooling the hard disk in the bracket 202. Thus, when removing or installing the fan 203, there is no need to open the case 201, thereby improving operational convenience.

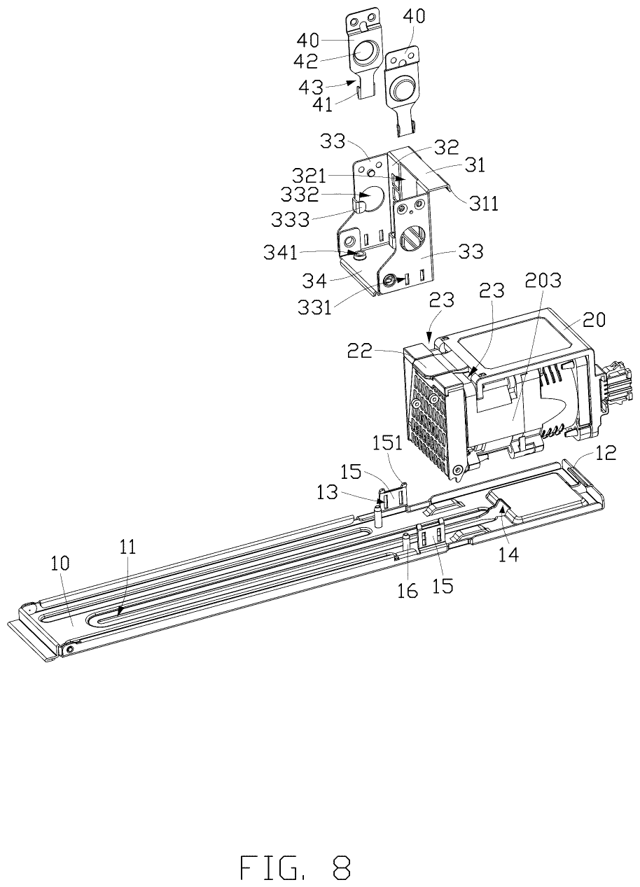

In some embodiments, as shown in FIG. 8, the sliding board 10 is provided with a flared slot 14 at the tail end of the sliding groove 11. The flared slot 14 communicates with the tail end of the sliding groove 11, and the width of the flared slot 14 gradually decreases toward the sliding groove 11 (along the A direction). The maximum width of the flared slot 14 is greater than or equal to the diameter of the head of the pin 206, and the minimum width of the flared slot 14 is equal to the width of the sliding groove 11. The pin 206 can pass through the flared slot 14 to penetrate the sliding board 10. When installing the sliding board 10 onto the case 201, the pin 206 passes through the flared slot 14 and enters the sliding groove 11. When removing the sliding board 10 from the case 201, the pin 206 is pulled out from the flared slot 14.

In some embodiments, as shown in FIG. 6 to FIG. 8, the lock 30 further includes a ventilation board 32 and two sideboards 33. The ventilation board 32 is located at the front side of the frame 20. The two sideboards 33 are respectively vertically disposed on opposite sides of the ventilation board 32, and the two sideboards 33 are positioned at the front side of the ventilation board 32. The pressing board 31 is vertically disposed at the rear side of the top of the ventilation board 32. Each sideboard 33 has one elastic piece 40 mounted on the inner side facing the other sideboard. The top end of each elastic piece 40 is fixed to the sideboard 33, and the bottom end of each elastic piece 40 is provided with a buckle 41. The sliding board 10 is provided with one stand board 15 on each of its opposite sides, each stand board 15 is provided with a positioning slot 13. When installing the lock 30 onto the sliding board 10, each stand board 15 is inserted into the gap between the elastic piece 40 and the sideboard 33 on the same side until the buckle 41 inserts into the positioning slot 13. Thus, the elastic piece 40 and the sideboard 33 can be protected by the sideboard 33, reducing the risk of accidental contact with the elastic piece 40.

In some embodiments, each sideboard 33 is provided with an observation slot 331. When the stand board 15 is inserted into the gap between the elastic piece 40 and the sideboard 33, the observation slot 331 aligns with the positioning slot 13, allowing the buckle 41 to pass through the positioning slot 13 and insert into the observation slot 331, thereby enhancing the stability of the lock 30 relative to the sliding board 10.

In some embodiments, each sideboard 33 is provided with a press hole 332, and each elastic piece 40 is provided with a bump 42. When the elastic piece 40 is not pressed, the bump 42 is exposed on the outer side of the sideboard 33 through the press hole 332. The user presses the bump 42 to deform the elastic piece 40, allowing the buckle 41 to be pulled out of the positioning slot 13, thereby improving operational convenience.

In some embodiments, the lock 30 further includes a bottom board 34, the bottom board 34 is provided with two guide holes 341, and the sliding board 10 is provided with two guide columns 16. When installing the lock 30 onto the sliding board 10, each guide column 16 is inserted into a corresponding guide hole 341 to guide the stand board 15 accurately into the gap between the elastic piece 40 and the sideboard 33 on the same side.

In some embodiments, the inner side of each sideboard 33 is provided with a guard board 333, the guard board 333 is located on the side of the elastic piece 40 facing away from the sideboard 33. When the elastic piece 40 deforms under pressure and contacts the guard board 333, the guard board 333 prevents further deformation of the elastic piece 40, limiting the extent of deformation and reducing the risk of the elastic piece 40 breaking due to excessive pressure.

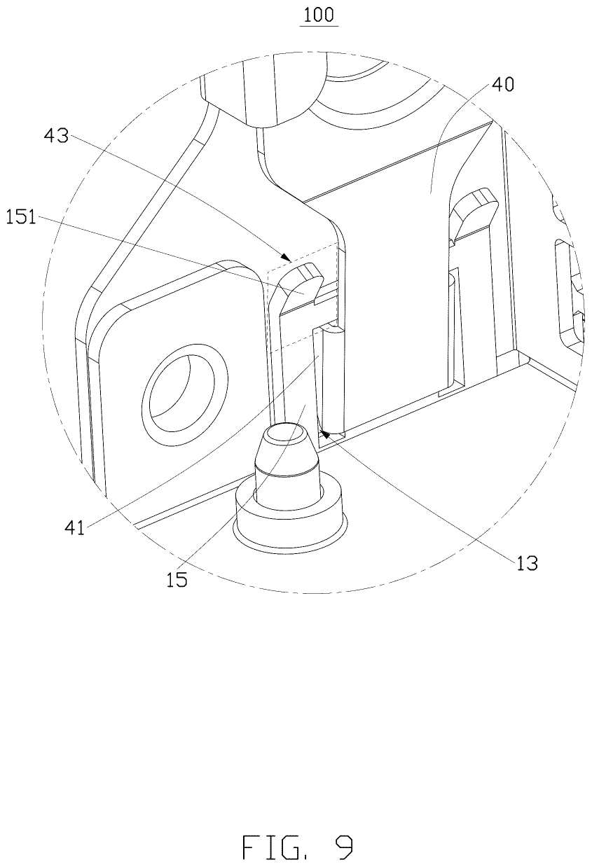

In some embodiments, as shown in FIG. 9, the top of each stand board 15 is provided with a protrusion 151, and each elastic piece 40 is provided with a notch 43. When the buckle 41 inserts into the positioning slot 13, the protrusion 151 simultaneously inserts into the notch 43, the protrusion 151 is used to limit the position of the elastic piece 40, enhancing the stability of the elastic piece 40.

In some embodiments, the ventilation board 32 is provided with an air vent 321, and the side of the pressing board 31 away from the ventilation board 32 is provided with two bent edges 311, the two bent edges 311 are bent downward relative to the pressing board 31. The top of the frame 20 is provided with a tongue 22, the tongue 22 extending toward the front side of the frame 20. The top of the frame 20 is provided with two hollow holes 23, the tongue 22 is located between the two hollow holes 23. When the lock 30 is installed on the sliding board 10, the two bent edges 311 are respectively inserted into the two hollow holes 23, and the tongue 22 is located between the two bent edges 311 and extends out of the air vent 321, thereby strengthening the connection between the lock 30 and the frame 20.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A server comprising:
a case with an opening;
a bracket placed in the case and movable between a working position and a maintaining position;
a chassis slidable into or out of the case through the opening; and
a fan positioned in the chassis, wherein
the bracket is configured for holding electronic devices;
when the chassis is fully slid into the case and the bracket is in the working position, the bracket is between the fan and the opening, the fan is configured for cooling the electronic devices; and
when the bracket is moved to the maintaining position from the working position, the bracket is moved out between the fan and the opening, so that the chassis is slidable out of the case such that the fan is removable from the chassis.

2. The server of claim 1, wherein the chassis comprises a sliding board, a frame, and a lock, the sliding board comprises a sliding groove, the case comprises a pin, the pin is insertable into the sliding groove and is slidable in the sliding groove, so that the sliding board is slidable on the case, the frame is configured for holding the fan, the lock is configured for locking the frame on the sliding board, the lock is located on a side of the frame facing towards the opening, when the lock is dismantled from the sliding board, the frame is removable from the sliding board.

3. The server of claim 2, wherein a tail end of the sliding board facing inwards the case comprises a plug-board, a back side of the frame facing inwards the case comprises a plug-slot, the plug-board is insertable into the plug-slot for locking the back side of the frame on the sliding board, the lock comprises a pressing board, when the lock locks the frame on the sliding board, the pressing board presses a front side of the frame facing outwards the case for locking the front side of the frame on the sliding board.

4. The server of claim 3, wherein the chassis further comprises a elastic piece, a top end of the elastic piece is located on the lock, a bottom end of the elastic piece comprises a buckle, the sliding board comprises a positioning slot, the buckle is insertable into the positioning slot for positioning the lock on the sliding board, when the elastic piece is pressed and deformed, the buckle is pulled out of the positioning slot, so that the lock is removable from the sliding board.

5. The server of claim 2, wherein an end of the sliding groove expands to form a flared slot, a pin-head of the pin is insertable into the flared slot, and the pin is slidable into the sliding groove from the flared slot, a diameter of the pin-head is larger than a width of the sliding groove, so that the sliding board is attached on the case, when the pin-head is pulled out from the flared slot, the sliding board is removable from the case.

6. The server of claim 4, wherein the lock further comprises a ventilation board and a sideboard, the ventilation board is located at a front side of the frame facing outwards the opening, the sideboard is perpendicular to the ventilation board, the pressing board is located on a top of the ventilation board, the elastic piece is located on the sideboard, the sliding board comprises a stand board, the positioning slot is located on the stand board, when the lock is positioned on the sliding board, the stand board is inserted into a gap between the elastic piece and the sideboard, so that the buckle is inserted into the positioning slot.

7. The server of claim 6, wherein the sideboard comprises an observation slot, when the stand board is inserted into the gap, the observation slot is aligned with the positioning slot, and the buckle is inserted into the positioning slot and the observation slot, the buckle is exposed through the observation slot.

8. The server of claim 6, wherein the sideboard comprises a press hole, the elastic piece comprises a bump, when the elastic piece is released, the bump is exposed through the press hole, the elastic piece is deformed by pressing the bump to pull out the buckle from the positioning slot.

9. The server of claim 6, wherein the lock further comprises a bottom board, the bottom board comprises two guide holes, the sliding board comprises two guide columns, when the lock is positioned on the sliding board, the two guide columns are inserted into the two guide holes, respectively, for guiding the stand board to be inserted into the gap.

10. The server of claim 6, wherein the sideboard comprises a guard board, the guard board extends to a side of the elastic piece away from the sideboard, when the elastic piece is deformed, the elastic piece moves towards the guard board, the guard board is configured for limiting the deformation of the elastic piece.

11. The server of claim 6, wherein the stand board comprises a protrusion on a top of the stand board, the elastic piece comprises a notch, when the buckle is inserted into the positioning slot, the protrusion is inserted into the notch, the protrusion is configured for positioning the buckle.

12. The server of claim 6, wherein the pressing board comprises a bent edge, the bent edge is bent towards the frame, a hollow hole is defined on a top of the frame, and the bent edge is inserted into the hollow hole, the ventilation board comprises an air vent, a tongue is defined on the top of the frame, the tongue extends through the air vent.

13. A server comprising:
a case with an opening;
a bracket placed in the case and movable between a working position and a maintaining position;
a fan; and
a chassis comprising:
a sliding board slidable into or out of the case through the opening, the sliding board comprising a positioning slot;
a frame located on the sliding board and configured for holding the fan;
a lock configured for pressing the frame on the sliding board; and
an elastic piece located on the lock, wherein
the elastic piece comprises a buckle, the buckle is inserted into the positioning slot to position the lock on the sliding board;
when the elastic piece is pressed and deformed, the buckle is pulled out of the positioning slot, so that the lock is removable from the sliding board, the bracket is configured for holding electronic devices;
when the chassis is fully slid into the case and the bracket is in the working position, the bracket is between the fan and the opening, the fan is configured for cooling the electronic devices; and
when the bracket is moved to the maintaining position from the working position, the bracket is moved out between the fan and the opening, so that the chassis is slidable out of the case such that the fan is removable from the chassis.

14. The server of claim 13, wherein a tail end of the sliding board facing inwards the case comprises a plug-board, a back side of the frame facing inwards the case comprises a plug-slot, the plug-board is insertable into the plug-slot for locking the back side of the frame on the sliding board, the lock comprises a pressing board, when the lock locks the frame on the sliding board, the pressing board presses a front side of the frame facing outwards the case for locking the front side of the frame on the sliding board.

15. The server of claim 14, wherein the lock further comprises a ventilation board and a sideboard, the ventilation board is located at a front side of the frame facing outwards the opening, the sideboard is perpendicular to the ventilation board, the pressing board is located on a top of the ventilation board, the elastic piece is located on the sideboard, the sliding board comprises a stand board, the positioning slot is located on the stand board, when the lock is positioned on the sliding board, the stand board is inserted into a gap between the elastic piece and the sideboard, so that the buckle is inserted into the positioning slot.

16. The server of claim 13, wherein the sideboard comprises an observation slot, when the stand board is inserted into the gap, the observation slot is aligned with the positioning slot, and the buckle is inserted into the positioning slot and the observation slot, the buckle is exposed through the observation slot;
the sideboard comprises a press hole, the elastic piece comprises a bump, when the elastic piece is released, the bump is exposed through the press hole, the elastic piece is deformed by pressing the bump to pull out the buckle from the positioning slot;
the stand board comprises a protrusion on a top of the stand board, the elastic piece comprises a notch, when the buckle is inserted into the positioning slot, the protrusion is inserted into the notch, the protrusion is configured for positioning the buckle.

17. A server comprising:
a case with an opening;
a bracket placed in the case and rotatable between a working position and a maintaining position;
a chassis slidable into or out of the case through the opening; and
a fan positioned in the chassis, wherein the bracket is rotatable around a shaft located on the case, the shaft is perpendicular to a direction of slide of the chassis relative to the case, the bracket is configured for holding electronic devices;
when the chassis is fully slid in the case and the bracket is in the working position, the bracket is between the fan and the opening, the shaft is on a side of the fan away from the opening, the fan is configured for cooling the electronic devices; and
when the bracket is moved to the maintaining position from the working position, the bracket is rotated out between the fan and the opening, so that the chassis is slidable out of the case such that the fan is removable from the chassis.

18. The server of claim 17, wherein the chassis comprises a sliding board, a frame, and a lock, the sliding board comprises a sliding groove, the case comprises a pin, the pin is insertable into the sliding groove and is slidable in the sliding groove, so that the sliding board is slidable on the case, the frame is configured for holding the fan, the lock is configured for locking the frame on the sliding board, the lock is located on a side of the frame facing towards the opening, when the lock is dismantled from the sliding board, the frame is removable from the sliding board.

19. The server of claim 18, wherein a tail end of the sliding board facing inwards the case comprises a plug-board, a back side of the frame facing inwards the case comprises a plug-slot, the plug-board is insertable into the plug-slot for locking the back side of the frame on the sliding board, the lock comprises a pressing board, when the lock locks the frame on the sliding board, the pressing board presses a front side of the frame facing outwards the case for locking the front side of the frame on the sliding board.

20. The server of claim 19, wherein the chassis further comprises a elastic piece, a top end of the elastic piece is located on the lock, a bottom end of the elastic piece comprises a buckle, the sliding board comprises a positioning slot, the buckle is insertable into the positioning slot for positioning the lock on the sliding board, when the elastic piece is pressed and deformed, the buckle is pulled out of the positioning slot, so that the lock is removable from the sliding board.
